(19) United States
(12) Patent Application Publication
(10) Pub. No.: US 2023/0394330 A1
(43) Pub. Date: Dec. 7, 2023

(54) A METHOD AND SYSTEM FOR DESIGNING AI MODELING PROCESSES BASED ON GRAPH ALGORITHMS

(71) Applicant: BEIJING BORRUI DATA TECHNOLOGY CO., LTD., Beijing (CN)

(72) Inventors: Ruimin LIU, Beijing (CN); Yang TAO, Beijing (CN); Shuihan YI, Beijing (CN)

(21) Appl. No.: 18/265,499

(22) PCT Filed: Jun. 10, 2022
(86) PCT No.: PCT/CN2022/098022

§ 371 Date: Jun. 6, 2023

(30) Foreign Application Priority Data
Sep. 14, 2021 (CN) 202111075665.5

(51) Int. Cl. G06N 5/022

(52) U.S. Cl. CPC G06N 5/022

(57) ABSTRACT

AI modeling process choreography method and system based on a graph algorithm is provided. The method includes: according to graph data obtained from a front end, generating a graph structure including a plurality of nodes; traversing nodes according to an execution sequence of the nodes in the graph structure, and adding, into a list to be executed, a target node needing to be executed; and traversing the nodes again according to the execution sequence, executing the current node when the current node is in the list, recording and outputting, otherwise, skipping the current node, recording and outputting, and writing states and execution results of the nodes into a database after traversing is completed, wherein the graph data includes node information of the nodes in the AI modeling process, and the node information includes input, output and parameters, so that data processing and model choreography can be combined together.

### CROSS-REFERENCE TO RELATED APPLICATIONS

This application claims priority to PCT Application No. PCT/CN2022/098022, having a filing date of Jun. 10, 2022, which claims priority to CN Application No. 202111075665.5, having a filing date of Sep. 14, 2021, the entire contents of both of which are hereby incorporated by reference.

### FIELD OF TECHNOLOGY

The following relates to the field of computer technology, and more specifically, to a method and system for designing AI modeling processes based on graph algorithms.

### BACKGROUND

The graph algorithm refers to a simple algorithm that used a specially designed line graph to find the answer, which can be used to describe the correlation between different nodes. Undirected graphs, directed graphs, and networks can use many common graph algorithms, these algorithms including: various traversing algorithms, algorithms for finding the shortest path, and algorithms for finding the lowest cost path in the network. Nowadays, most of the application scenarios of graph algorithms are to find the shortest path, to find the optimal solution, and a few use graph algorithms to do process orchestration work graph algorithms.

In recent years, AI (Artificial Intelligence) technology is developing rapidly, more and more diversified AI technology achievements are emerging and applied to life, such as image recognition, voice recognition, etc. AI is, by its nature, a simulation of the information processing process of the human mind. After feature analysis the feature data recorded in a specific scene by using statistics and other methods in modern electronic computers, an AI model is built and trained by selecting a model and algorithm, a prediction model is evaluated and generated, and the prediction model is used to predict scenes in similar scenes, such a process is called AI modeling, and AI modeling is divided into three stages: data processing and model building, and model training.

At present, in the process arrangement of AI modeling, the data processing and modeling processes are independent of each other, only the order of process execution is arranged, and the data is not circulated among systems but kept in a fixed location, which lacks flexibility in the process arrangement, in addition, due to the different characteristics of graph algorithm and tree structure, it can only be executed from the beginning, and there are some successfully executed nodes are repeatedly executed, which wastes computational resources.

Therefore, how to improve the flexibility of AI modeling process scheduling and reduce the utilization of computational resources is a technical problem to be solved.

### SUMMARY

An aspect relates to a method for designing AI modeling processes based on graph algorithms, to solve the technical problems of lack of flexibility and waste of computational resources in the designing of AI modeling processes in the conventional art.

In an embodiment, the method includes:
generating a graph structure including a plurality of nodes based on graph data obtained from a front-end;
traversing each node in accordance with the execution order of each node in the graph structure and adding the target node to the list of to be executed;
traversing each node again according to the execution order, executing the current node if it is in the list of to be executed and recording the output, else skipping the current node and recording the output, and writing the state and execution result of each node to the database after the traversing is completed;
wherein the graph data includes node information of each node in the AI modeling process, the node information includes input and output and parameters.

In some embodiments of this application, traversing each node in accordance with the execution order of each node in the graph structure and adding the target node to the list of to be executed, by:
determining in turn whether the current node conforms to the predetermined rules according to the execution order, if so, adding the current node as the target node to the list of to be executed;
wherein the predetermined rules include the current node for the re-submitted parameters, or the current node for the last unsuccessful execution of the node, or the current node's parent node in the list of to be executed.

In some embodiments of this application, before traversing each node in accordance with the execution order of each node in the graph structure and adding the target node to the list of to be executed, the method further comprises:
searching the graph structure based on the depth first search function;
determining the execution order based on the search results.

In some embodiments of this application, the graph structure includes input and output nodes of the node, input and output parameters of the node, parameter information of the node, whether the node needs to record parameter information, the name of the node, and the function called by the node.

In some embodiments of this application, the graph data is the data in json format.

Accordingly, embodiments of the present invention also propose a system for designing AI modeling processes based on graph algorithms, the system comprises:
a generation module, for generating a graph structure including a plurality of nodes, representing an AI process, based on graph data obtained from a front-end;
a first traversing module, for traversing each node in accordance with the execution order of each node in the graph structure and adding the target node to the list of to be executed;
a second traversing module, for traversing each node again according to the execution order, executing the current node when it is in the list of to be executed and recording the output, otherwise skipping the current node and recording the output, and writing the state and execution result of each node to the database after the traversing is completed;
wherein the graph data includes node information of each node in the AI modeling process, the node information includes input and output and parameters.

In some embodiments of this application, the first traversing module, specifically for:
determining in turn whether the current node conforms to the predetermined rules according to the execution order, if so, adding the current node as the target node to the list of to be executed;
wherein the predetermined rules include the current node for the re-submitted parameters, or the current node for the last unsuccessful execution of the node, or the current node's parent node in the list of to be executed.

In some embodiments of this application, the system further comprises a search module for:
searching the graph structure based on the depth first search (DFS) function;
determining the execution order based on the search results.

In some embodiments of this application, the graph structure includes input and output nodes of the node, input and output parameters of the node, parameter information of the node, whether the node needs to record parameter information, the name of the node, and the function called by the node.

In some embodiments of this application, the graph data is the data in json format.

By applying the above technical solutions, according to the graph data obtained from the front-end to generate a graph structure including a plurality of nodes; according to the graph structure of the nodes in the order of execution of each node and the target node into the list to be executed; according to the order of execution again traversed each node, in the current node in the list to be executed when the execution of the current node and record the output, otherwise skip the current node and record the output, and write the state and execution result of each node to the database after the traversing is completed wherein the graph data includes the node information of each node in the AI modeling process, and the node information includes the input and output and parameters, so that the data processing and model arrangement can be combined together, which improves the flexibility of the AI modeling process arrangement, and the nodes that have been executed successfully are not repeatedly executed, avoiding The nodes that have been successfully executed are not repeatedly executed, avoiding the waste of computational resources.

### BRIEF DESCRIPTION

Some of the embodiments will be described in detail, with references to the following Figures, wherein like designations denote like members, wherein:

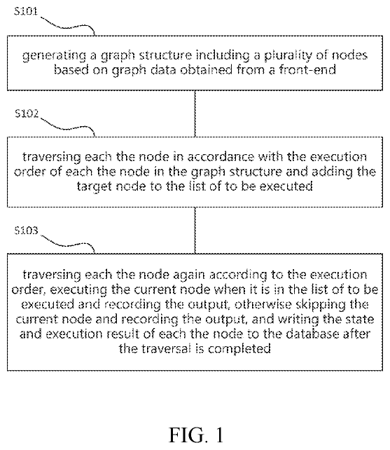

FIG. 1 illustrates a flow diagram of a method for designing AI modeling processes based on graph algorithms proposed by an embodiment of the present invention;

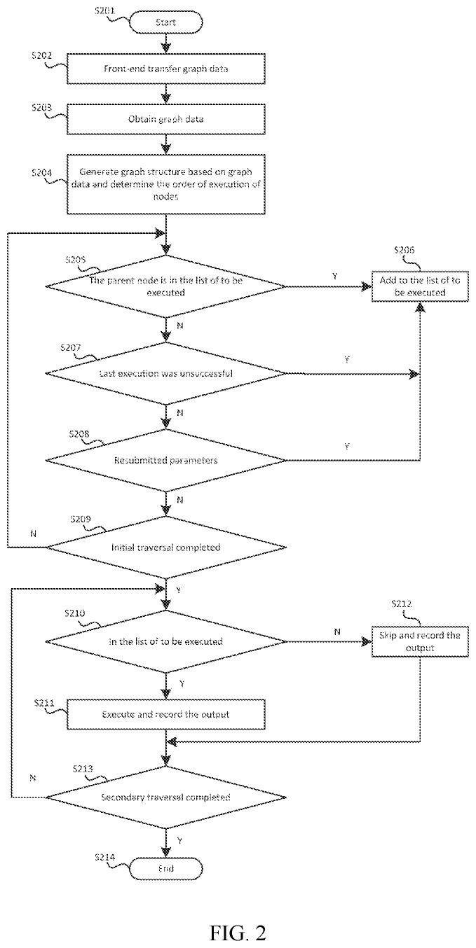

FIG. 2 illustrates a flow diagram of a method for designing AI modeling processes based on graph algorithms proposed by another embodiment of the present invention; and

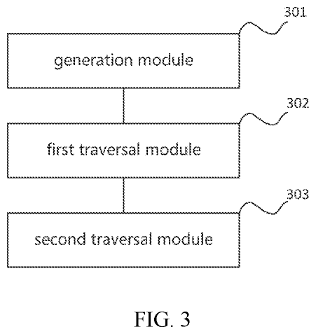

FIG. 3 illustrates a schematic diagram of the structure of a system for designing AI modeling processes based on graph algorithms proposed by an embodiment of the present invention.

### DETAILED DESCRIPTION

The following is a clear and complete description of the technical solutions in the embodiments of this application in conjunction with the drawings in the embodiments of this application, and it is clear that the embodiments described are only part of the embodiments of this application, not all of them. Based on the embodiments in this application, all other embodiments obtained by a person of ordinary skill in the conventional art without creative labor fall within the scope of protection of this application.

Embodiments of the present application provide a method for designing AI modeling processes based on graph algorithms, as shown in FIG. 1, comprising the following steps:

Step S101, generating a graph structure including a plurality of nodes based on graph data obtained from a front-end;

In this implementation, the front-end can be a browser access webUI (Website User Interface), the front-end can be dragged and dropped to arrange the process, after the execution of the process can obtain the execution status of the back-end process and the log of the execution. The graph data includes the node information of each node in the AI modeling process, and the node information includes the input and output and parameters, and the graph structure including multiple nodes can be generated according to the graph data, and the graph structure can be a graph structure according to the predefined type, for example, if the predefined type is directed graph, the graph structure is the graph structure of directed graph, which is a directed acyclic graph.

In order to generate an accurate diagram structure and to accurately execute the process, in some embodiments of this application, the graph structure includes input and output nodes of the node, input and output parameters of the node, parameter information of the node, whether the node needs to record parameter information, the name of the node, and the function called by the node.

A person skilled in the conventional art may choose a different diagram structure according to practical needs, which does not affect the scope of protection of this application.

In order to generate an accurate graph structure, in some embodiments of the present application, the graph data is the data in json format.

In this embodiment, the diagram data is in json format, which is a string containing the information of each node of the process.

The person skilled in the conventional art can choose other formats of diagram data according to the actual needs, which does not affect the scope of protection of this application.

Step S102, traversing each node in accordance with the execution order of each node in the graph structure and adding the target node to the list of to be executed.

In this embodiment, there is a sequential order of execution for each node in the graph structure, and based on this order of execution, each node is traversed and the target node is added to the list to be executed.

In order to reliably add the target node to the list of to be executed, in some embodiments of the present application, each node is traversed and the target node is added to the list of to be executed in accordance with the order of execution of each node in the graph structure, specifically:
determining in turn whether the current node conforms to the predetermined rules according to the execution order, if so, adding the current node as the target node to the list of to be executed;
wherein the predetermined rules include the current node for the re-submitted parameters, or the current node for the last unsuccessful execution of the node, or the current node's parent node in the list of to be executed.

In this embodiment, the current node is judged in order of execution, and if the current node loads the preset rules, the current node is added to the list of nodes to be executed as the target node.

The person skilled in the conventional art can set different preset rules according to the actual situation, which does not affect the scope of protection of this application.

In order to accurately determine the order of execution of the nodes in the graph structure, in some embodiments of the present application, before traversing each node in accordance with the order of execution of the nodes in the graph structure and adding the target node to the list of to be executed, the method further comprising:
searching the graph structure based on the depth first search function;
determining the execution order based on the search results.

In this implementation, a depth-first search function is used to determine the order of execution. The depth-first search is a type of graph algorithm, and the process is briefly described as going deeper into each possible branching path until it cannot go any deeper, and each node can only be visited once. The specific process of searching the graph structure based on the depth-first search function is obvious to those skilled in the conventional art, and will not be repeated here.

The person skilled in the conventional art may also determine the order of execution based on other means, such as breadth-first search, which does not affect the scope of protection of this application.

Step S103, traversing each node again according to the execution order, executing the current node when it is in the list of to be executed and recording the output, otherwise skipping the current node and recording the output, and writing the state and execution result of each node to the database after the traversing is completed.

In this implementation, the nodes are traversed twice in the order of execution, and the target node is added to the execution list during the first traversing, and the current node is executed and output is recorded when the current node is in the execution list during the second traversing, otherwise the current node is skipped and output is recorded, and the status and execution results of each section are written to the database after the traversing is completed, waiting for the front-end to retrieve the status for display.

By applying the above technical solutions, according to the graph data obtained from the front-end to generate a graph structure including a plurality of nodes; according to the execution order of each node in the graph structure traversing each node and add the target node to the list of to be executed; according to the execution order traversing each node again, in the current node in the list of to be executed to execute the current node and record the output, otherwise skip the current node and record the output, and write the state and execution result of each node to the database after the traversing is completed; wherein the graph data includes node information of each node in the AI modeling process, and the node information includes input and output and parameters, so that the data processing and model scheduling can be combined together, which improves the flexibility of the AI modeling process scheduling, and the nodes that have been executed successfully are not repeatedly executed, avoiding The nodes that have been successfully executed are not repeatedly executed and the waste of computational resources is avoided.

In order to further elaborate the technical ideas of embodiments of the present invention, the technical solution of embodiments of the present invention is described in the context of a specific application scenario.

This application embodiment provides a graph algorithm-based AI modeling process orchestration method, as shown in FIG. 2, comprising the following steps.

Step S201, start.

Step S202, transmitting graph data at the front end.

Step S203, obtain graph data.

Step S204, generating a graph structure based on the graph data and determining the execution order of the nodes.

In this step, the execution order is determined after searching the graph structure based on the depth-first search function.

Step S205, the parent node is in the list of to be executed, if it is, step S206 is executed, otherwise step 207 is executed.

In this step, the first traversing of each node in execution order is performed to determine whether the parent node of the current node is in the pending execution list.

Step S206, add the node to the pending execution list.

Step S207, the last execution is unsuccessful, if so, step S206 is executed, otherwise, step S208 is executed.

In this step, determine whether the current node is the node whose last execution was unsuccessful.

Step S208, resubmit the parameter, if so, step S206 is executed, otherwise, step S209 is executed.

In this step, determine whether the current node is the node that has resubmitted the parameters.

Step S209, the first traversing is completed, if so, step S210 is executed, otherwise, step S205 is executed.

Step S210, the list of nodes to be executed, if so, step S211 is executed, otherwise, step S212 is executed.

In this step, the nodes are traversed twice in the order of execution, and the nodes are judged to be in the list of pending execution.

Step S211 is executed and the output is recorded.

Step S212 is skipped and the output is recorded.

Step S213, the second traversing is completed, if so, step S214 is executed, otherwise, step S210 is executed.

Step S214, end.

It should be noted that the order of execution of steps S205, S207, S208 can be interchanged.

Through the application of the above technical solutions, data processing and model orchestration can be combined together, so that data can be circulated between the systems, improving the flexibility of processing; in addition, will not repeat the execution of the successfully executed node, to determine the implementation status of each node, for the data node can view the data can be saved node data exported to other scenes to demonstrate.

The present application embodiment also presents a graph algorithm-based AI modeling process orchestration system, as shown in FIG. 3, the system comprising.
a generation module 301, for generating a graph structure including a plurality of nodes based on graph data obtained from a front-end, which represents an AI process
a first traversing module 302, for traversing each node in the order of execution of each node in the graph structure and adding the target node to the list of to be executed.
second traversing module 303, for traversing each node again in the execution order, executing the current node when the current node is in the list of to be executed and recording the output, otherwise skipping the current node and recording the output, and writing the state and execution result of each node to the database after the traversing is completed;
wherein the graph data includes node information of each node in the AI modeling process, the node information includes input and output and parameters.

In a specific application scenario of this application, the first traversing module 302, specifically for.
determining, in order of the execution, whether the current node conforms to predetermined rules, and if so, adding the current node as the target node to the list of to be executed.

Wherein the predetermined rules include the current node is a node that has resubmitted parameters, or the current node is a node whose last execution was unsuccessful, or the parent node of the current node is in the list of to be executed.

In a specific application scenario of the present application, the system further comprising a search module for.
searching the graph structure based on a depth-first search function
determining the execution order based on the search results.

In this application specific application scenario, the graph structure includes input and output nodes of the node, input and output parameters of the node, parameter information of the node, whether the node needs to record parameter information, name of the node, and the way the node is called.

In the specific application scenario of this application, the graph data is data in j son format.

Although the invention has been illustrated and described in greater detail with reference to the exemplary embodiment, the invention is not limited to the examples disclosed, and further variations can be inferred by a person skilled in the art, without departing from the scope of protection of the invention.

For the sake of clarity, it is to be understood that the use of “a” or “an” throughout this application does not exclude a plurality, and “comprising” does not exclude other steps or elements.

1-10. (canceled)

11. A method for designing AI modeling processes based on graph algorithms, wherein the method comprises:
generating a graph structure including a plurality of nodes based on a graph data obtained from a front-end;
traversing each node according to an execution order of each node in the graph structure and adding the target node to the list of to be executed;
traversing each node again according to the execution order, executing current node if the current node is in the list of to be executed and recording output, and if not, skipping the current node and recording an output, and then writing a state and an execution result of each node to a database after the traversing is completed;
wherein the graph data includes node information of each node in the AI modeling process, the node information includes input, output, and parameters;
before traversing each node according to the execution order of each the node in the graph structure and adding the target node to the list of to be executed, the method further comprises:
searching the graph structure based on the depth first search function;
determining the execution order based on the search results;
traversing each node according to the execution order of each node in the graph structure and adding the target node to the list of to be executed, specificity by:
determining in turn whether the current node conforms to the predetermined rule according to the execution order, if so, adding the current node as the target node in the list of to be executed;
wherein the predetermined rule includes the current node is the node that has re-submitted parameters, or the current node is the node that last execution is unsuccessful, or the parent node of the current node is in the list of to be executed.

12. The method according to claim 11, wherein the graph structure includes input and output nodes of the node, input and output parameters of the node, parameter information of the node, whether the node needs to record the parameter information, the name of the node, the function called by the node.

13. The method according to claim 11, wherein the graph data is the data in j son format.

14. A system for designing AI modeling processes based on graph algorithms, wherein the system comprises:
a generating module, for generating a graph structure including a plurality of nodes, representing an AI process, based on a graph data obtained from a front-end;
a first traversing module, for traversing each node according to the execution order of each node in the graph structure and adding the target node to the list of to be executed;
a second traversing module, for traversing each node again according to the execution order, executing the current node if it is in the list of to be executed and recording output, else skipping the current node and recording output, and then writing the state and execution result of each node to the database after the traversing is completed;
wherein the graph data includes node information of each node in the AI modeling process, the node information includes input, output and parameters;
the first traversing module, specifically for:
determining in turn whether the current node conforms to the predetermined rules according to the execution order, if so, adding the current node as the target node to the list of to be executed;
wherein the predetermined rules include the current node is the node that has re-submitted parameters, or the current node is the node that the last execution is unsuccessful, or the parent node of the current node is in the list of to be executed;
the system further comprises a searching module for:
searching the graph structure based on the depth first search function;
determining the execution order based on the search results.

15. The system according to claim 14, wherein the graph structure includes input and output nodes of the node, input and output parameters of the node, parameter information of the node, whether the node needs to record the parameter information, the name of the node, and the function called by the node.

16. The system according to claim 14, wherein the graph data is the data in json format.
